(19) United States
(12) Patent Application Publication
(10) Pub. No.: US 2004/0184327 A1
(43) Pub. Date: Sep. 23, 2004

(54) Semiconductor memory device and test method

(76) Inventor: Yuichi Okuda, Higashimurayama (JP)

Correspondence Address: ANTONELLI, TERRY, STOUT & KRAUS, LLP, 1300 NORTH SEVENTEENTH STREET, SUITE 1800, ARLINGTON, VA, 22209-9889, US

(21) Appl. No.: 10/767,054

(22) Filed: Jan. 30, 2004

(30) Foreign Application Priority Data
Jan. 31, 2003 (JP) 2003-023019

(51) Int. Cl. G11C 7/00

(52) U.S. Cl. 365/199

(57) ABSTRACT

There are provided a semiconductor memory device incorporating an ECC which enables an efficient test with high accuracy by a simplified structure and can shorten the test time and a test method thereof. A semiconductor memory device has an ECC circuit capable of correcting, from an m-bit information code and an n-bit check code stored in an information storing part, an error of the information code to x bits, and a parallel test circuit for receiving an information code and a check code for test with the same bits stored in the information storing part and deciding a defect with the x+1 bits or more as being defective. The parallel test circuit decides a defect with the x+1 bits or more for one piece of position information as a defective chip.

### BACKGROUND OF THE INVENTION

The present invention relates to a semiconductor memory device and a test method thereof. The present invention relates mainly to a technique effective to be used for a dynamic random access memory device mounting an ECC circuit and a test facilitation technique thereof.

Japanese Unexamined Patent Publication No. Hei 11(1999)-025689 is disclosed as an example of a semiconductor memory device test method and a semiconductor memory device mounting an ECC circuit and provided with means for deciding whether there are no errors, a 1-bit error occurs, or an error with 2 bits or more occurs by noting that there is no problem of using it as a non-defective product even when including a 1-bit hard error.

[Patent Document 1]

Japanese Unexamined Patent Publication No. Hei 11(1999)-025689

### SUMMARY OF THE INVENTION

In the description of Patent Document 1, on the assumption that an ECC decoder is normal, regarding an information bit and a check bit as one information bit, an ECC generator for test is added thereto, and an error correction signal formed by the ECC decoder is compared with write data WD corresponding to the inputted information bit and test data TD as the check bit to detect a defect with 2 bits or more.

The technique of Patent Document 1 requires, as the ECC decoder, a circuit for forming read data RD by an information bit and a check bit for normal operation and a circuit for forming an information bit and a check bit error-corrected by a check bit generated by the ECC generator for test, regarding an information bit and a check bit as one information bit, for test operation, and the ECC generator for test. It also requires an input circuit for inputting the test data TD for test and an output circuit for outputting the check bit. The circuit size of the ECC decoder, the ECC generator for test, the input circuit and the output circuit, which are used only for test, is increased. Along with it, the number of external terminals is increased and any defects in the ECC decoder cannot be precisely detected. Since any defective locations cannot be specified, a redundancy circuit for switching a defective cell to a preliminary cell cannot be used.

To shorten time for defect selection, in a DRAM having a large memory capacity, it is typical to employ a test method called a parallel test, which tests a number of bits in parallel. In Patent Document 1, however, no consideration is given to the parallel test for shortening the test time. When it is applied to a DRAM as-is, the test time is longer so that an increase in the test cost will reflect directly on the product cost.

An object of the present invention is to provide a semiconductor memory device mounting an ECC circuit which enables an efficient test with high accuracy by a simplified structure and a test method thereof. Another object of the present invention is to provide a semiconductor memory device incorporating an ECC capable of shortening test time by a simplified structure and a test method thereof. The above and other objects and novel features of the present invention will be apparent from the description of this specification and the accompanying drawings.

A representative invention disclosed in the present invention will be simply described as follows. A semiconductor memory device has an ECC circuit capable of correcting, from an m-bit information code and an n-bit check code stored in an information storing part, an error of the information code to x bits, and a parallel test circuit for receiving an information code and a check code for test with the same bits stored in the information storing part and deciding a defect with the x+1 bits or more as being defective.

Another representative invention disclosed in the present invention will be simply described as follows. A test method of a semiconductor memory device having an ECC circuit capable of correcting, from an m-bit information code and an n-bit check code stored in an information storing part, an error of the information code to x bits, and a test circuit for receiving an information code and a check code in the information storing part, wherein an information code and a check code for test with the same bits are stored in the information storing part, the stored information code and check code for test are transmitted to the test circuit, and a defect with the x+1 bits or more for one piece of position information is decided as being defective.

### BRIEF DESCRIPTION OF THE DRAWINGS

FIG. 1 is a block diagram showing an embodiment of a DRAM to which the present invention is applied;

FIG. 2 is a block diagram showing an embodiment of a 6-bit input parallel decision circuit according to the present invention;

FIG. 3 is a block diagram showing an embodiment of a parallel test decision circuit according to the present invention;

FIG. 4 is a block diagram showing an embodiment of a pseudo independent decision circuit according to the present invention;

FIG. 5 is a block diagram showing an embodiment of a parallel test decision circuit when employing an ECC with 128+8 bits according to the present invention;

FIG. 6 is a block diagram showing a data flow at normal operation of a semiconductor memory device according to the present invention;

FIG. 7 is a block diagram showing a data flow when allowing memory cells for parity of a semiconductor memory device according to the present invention to be controllable;

FIG. 8 is a block diagram showing a data flow when allowing the memory cells for parity according to the present invention to be observable;

FIG. 9 is a block diagram showing an embodiment of a layout example of the DRAM according to the present invention;

FIG. 10 is an overall block diagram showing an embodiment of a dynamic RAM according to the present invention; and

FIG. 11 is a circuit diagram showing an embodiment of a DRAM according to the present invention.

### DETAILED DESCRIPTION OF THE PREFERRED EMBODIMENTS

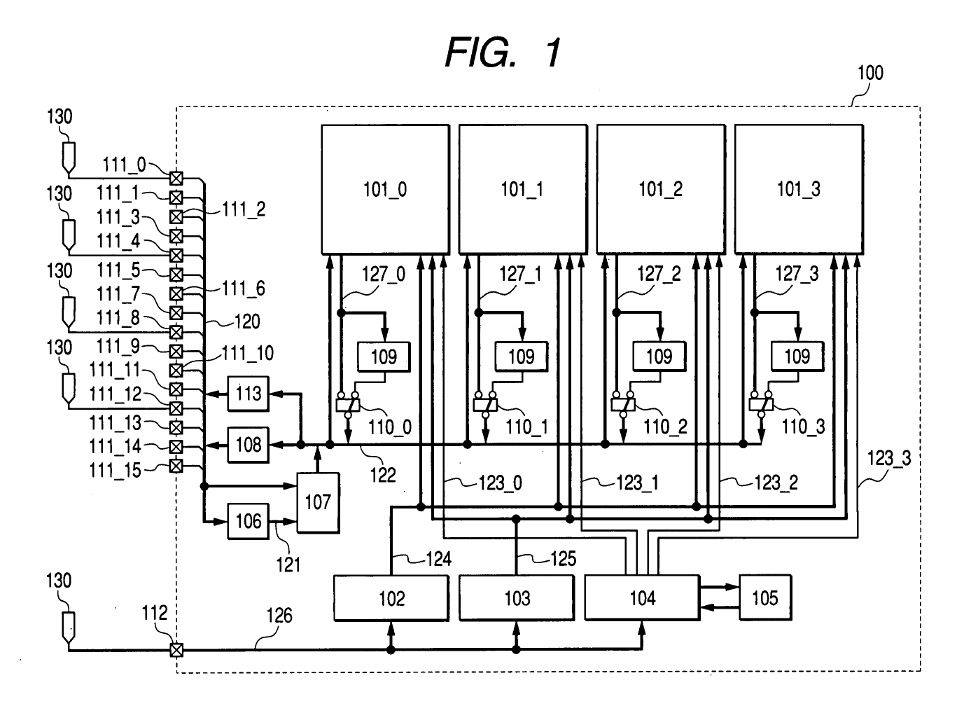

FIG. 1 shows a schematic block diagram of an embodiment of a DRAM according to the present invention. The circuit blocks in the drawing are formed on one semiconductor substrate by a known semiconductor integrated circuit manufacturing technique. The numeral 100 denotes a DRAM chip employing an ECC according to the present invention. Not being particularly limited, in the present invention, it is a 16-pin chip of the DDR SDRAM standards. Not being particularly limited, the ECC capable of correcting a 1-bit error by adding 4-bit parity for each 8-bit data is used.

In the DRAM chip 100, the numerals 101_0 to 101_3 denote a memory mat; the numeral 102, a row address decoder; the numeral 103, a column address decoder; the numeral 104, a command decoder; the numeral 105, a resister; the numeral 106, a parity generation circuit; the numeral 107, a parallel test selector; the numeral 108, an ECC decoder; the numeral 109, a parallel test decision circuit; the numerals 110_0 to 110_3, a decision result selector; the numerals 111_0 to 111_15, a data pin; the numeral 112, a command and address pin; the numeral 113, a pseudo independent decision circuit; the numeral 120, an input/output bus; the numeral 121, parity data; the numeral 122, a global I/O bus; the numerals 123_0 to 123_3, a memory mat select signal; the numeral 124, a row select signal; the numeral 125, a column select signal; the numeral 126, a command and address signal; the numerals 127_0 to 127_3, a main amp output signal; and the numeral 130, a test pin of memory tester. Originally, there are a number of the command and address pins 112. In this embodiment, they need not be particularly discriminated and only one of them is shown.

The writing operation of the DRAM chip 100 employing the ECC in FIG. 1 is performed by the following 1) to 5).

1) A row address specification command is inputted to the command and address pin 112 with a row address and a memory mat select signal.

2) The row address decoder 102 outputs the row select signal 124 to activate the specified row of the memory mat specified by the command decoder 104.

3) A write command is inputted to the command and address pin 112 with a column address and a memory mat select signal to input data to the data pin 111.

4) Since the DRAM chip 100 employs the ECC, the 8-bit parity data 121 is generated by the parity generation circuit 106 from the inputted 16-bit data. The parallel test selector 107 selects data 16 bits and parity 8 bits to output them to the global I/O 122 (24 bits).

5) The column address decoder 103 outputs the column select signal 125. The data of the global I/O 122 is written into the memory cell according to the column select signal 125 in the memory mat specified by the command decoder 104.

The reading operation of the DRAM chip 100 employing the ECC in FIG. 1 is performed by the following 1) to 5).

1) A row address specification command is inputted to the command and address pin 112 with a row address and a memory mat select signal.

2) The row address decoder 102 outputs the row select signal 124 to activate the specified row of the memory mat specified by the command decoder 104 so as to amplify the contents of the memory cells in the sense amp in the memory mat 101.

3) A write command is inputted to the command and address pin 112 with a column address and a memory mat select signal.

4) The column address decoder 103 outputs the column select signal 125. Data is selected from the main amp output signal according to the column select signal 125 in the memory mat specified by the command decoder 104 so as to be finally amplified in the main amp. The main amp output signal 127 is outputted to the global I/O 122.

5) Since the DRAM chip 100 employs the ECC, the main amp output has 24 bits obtained by adding parity 8 bits to data 16 bits. The ECC decoder 108 corrects the error to output 16-bit data via the input/output bus 120 to the data pin 111.

Since the DRAM chip 100 is a DDR SDRAM, the main amp output for two words is originally outputted to be switched at outputting, thereby enabling a wide-band operation. In one reading/writing operation, a plurality of words (typically, 2 to 8 words/command) are always processed. They are omitted in the description.

Based on the above, parallel tests of the DRAM chip 100 will be described. First, a parallel test when not employing the ECC will be described. Basically, the parallel test is a technique of connecting a number of DRAM chips 100 to a memory tester to conduct the test in parallel, thereby reducing the test cost. The number of the test pins 130 of memory tester is limited. Depending on how many test pins 130 are used for one chip, the processing ability for one memory tester is decided. The reduction of the number of test pins per chip is important for reducing the test cost. Since the command and address given to each chip is shared, the test pins connected to the command and address pins can be shared among a number of chips. In particular, the test pins connected to the data pins for receiving test results must be prepared for each chip. The reduction of the number of the test pins connected to the data pins provides a high test cost reduction effect.

As shown in FIG. 1, the DRAM chip 100 is a memory of a 16-I/O 4-mat structure. In the parallel test, typically, 16 bits×4=64 bits are tested in parallel. The number of the test pins connected to 16 data pins of each chip can be reduced to four. In simple calculation, the number of chips connected to the memory tester is four times. The four mats are tested in parallel to shorten one test time to ¼. In combination of the two effects, the processing ability of the memory tester is 16 times. The test cost is found to be reduced very significantly.

The parallel test method as an assumption of this embodiment is performed according to the procedure of the following 1) to 3).

1) A command which is not allowed in the standards is used to move to parallel test mode. That is, the command of the parallel test mode is decided by a bit pattern which is not used in the existing SDRAM. The movement to the parallel test is decoded by the command decoder 104 to write a flag indicating the parallel test into the register 105. Other circuits are operated in parallel test mode with reference to the flag of the register 105.

2) Data writing is performed. Here, only 4-bit data is specified. As understood from FIG. 1, only four data pins 111_0, 111_4, 111_8 and 111_12 are connected to the test pins 130 of memory tester of the data pins 111_0 to 111_15. Other data pins are released. For convenience of check performed thereafter, the data on the data pins 110_0, 110_4, 110_8 and 110_12 are the same.

The parallel test selector 107 recognizes the operation in parallel test mode and allocates the data inputted from the data pin 110_0 to bits 0, 1, 2 and 3. Similarly, the data inputted from the data pin 110_4 is allocated to bits 4, 5, 6 and 7, the data inputted from the data pin 110_8 is allocated to bits 8, 9, 10 and 11, and the data inputted from the data pin 110_12 is allocated to bits 12, 13, 14 and 15. As a result, the same data is written into all bits.

In the command and address pin 112, the command and address are operated as normal except for memory mat specification. In the normal operation, only the specified memory mat is activated to perform writing/reading. In writing in the parallel test, the four mats are activated in parallel to write the same data into the memory cells in the same row and column of the four memory mats. In the normal operation, the memory mat select signals 123_0 to 123_3 in which only one of the four signals is transited to Hi (high level) are all transited to Hi in the parallel test to activate the four memory mats 101_0 to 101_3. In the parallel test, the memory mat specification is invalid and the test pins 130 of memory tester may be released without being connected.

3) Data reading is performed. In the same manner as the data writing, the four mats are read in parallel. The same data is written into all bits in the mats. When the memory cells are not abnormal, the same data should be read. The parallel test decision circuits 109 decide whether all bits are in coincidence or not. When all bits are in coincidence, acceptance is decided. When even 1 bit is non-coincident, rejection is decided. The decision result selectors 110_0 to 110_3 output the decision results to different bits, respectively, and other bits are unselected. Specifically, the decision result selector 110_0 outputs the decision result to bit 0, the decision result selector 110_1 outputs the decision result to bit 4, the decision result selector 110_2 outputs the decision result to bit 8, and the decision result selector 110_3 outputs the decision result to bit 12.

4) As a result, the memory tester can individually receive the decision results of the mats. That is, it receives the decision result of the memory mat 101_0 from the data pin 111_0, the decision result of the memory mat 101_1 from the data pin 111_4, the decision result of the memory mat 101_2 from the data pin 111_8, and the decision result of the memory mat 101_3 from the data pin 111_12. When being decided as being rejected, redundancy relief is performed in the corresponding memory mat, row and column. Any memory which has not been relieved by the redundancy relief is discarded as a defective product.

The case of the DRAM according to the present invention employing the ECC in the DRAM chip 100 will be considered here. Basically, because of a 4-mat structure with 16 I/O bits and 8 parity bits, the parallel test of (8+4)×4=96 bits may be conducted in parallel. That is, at writing, the data inputted from the data pin 110_0 is allocated to data bits 0, 1, 2 and 3 and parity bits 0 and 1. Similarly, the data inputted from the data pin 110_4 is allocated to data bits 4, 5, 6 and 7 and parity bits 2 and 3, the data inputted from the data pin 110_8 is allocated to data bits 8, 9, 10 and 11 and parity bits 4 and 5, and the data inputted from the data pin 110_12 is allocated to data bits 12, 13, 14 and 15 and parity bits 6 and 7. At reading, whether all of 24 bits of the main amp output signal 127 are in coincidence or there are any non-coincident bits is decided.

In the DRAM according to the present invention, as described later, one of the objects to employ the ECC is to cope with retention defect of memory data. In other words, the refresh interval (cycle) of the DRAM is made longer. In this case, when there is a 1-bit defect in 8+4 bits as an ECC unit, it must be decided as a non-defective product. As described above, however, in the parallel test for deciding whether all bits are in coincidence or not, the 1-bit defect is decided as being rejected. To avoid this, a method for testing all bits without using the parallel test can be considered. It increases the test cost, which is hard to accept.

Accordingly, the present invention employs a parallel decision circuit corresponding to the ECC. Since any retention defect is relieved by the ECC, an acceptance decision is given to a 1-bit defect in 8+4 bits. There requires a parallel decision circuit for detecting 1-bit non-coincidence as well as all bits coincidence to output an acceptance decision.

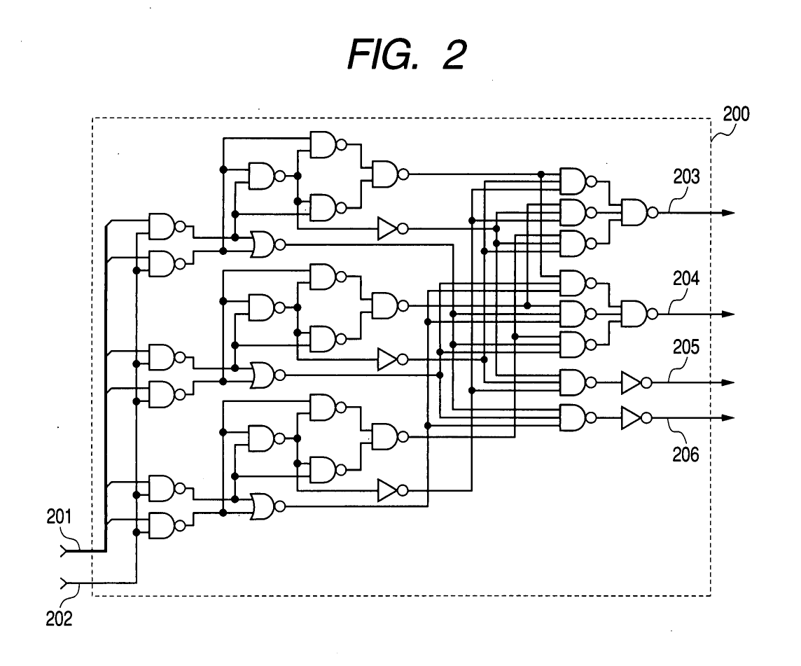

FIG. 2 shows a circuit diagram of an embodiment of a parallel decision circuit according to the present invention. The drawing shows a 6-bit input parallel decision circuit. The numeral 200 denotes a 6-bit input parallel decision circuit; the numeral 201, a 6-bit input; the numeral 202, a decision circuit valid signal; the numeral 203, a 1-bit Hi (high level) decision output; the numeral 204, a 1-bit Lo (low level) decision output; the numeral 205, an all bits Lo (low level) output; and the numeral 206, an all bits Hi (high level) output.

In detail description, when the decision circuit valid signal 202 is a Hi input, the 6-bit input parallel decision circuit 200 performs a decision of the 6-bit input 201. When the 6-bit input 201 is all bits Hi, Hi is outputted to the all bits Hi decision output 206 and other outputs output Lo. Similarly, when the 6-bit input 201 is all bits Lo, Hi is outputted to the all bits Lo decision output 205 and other outputs output Lo. When an arbitrary bit of the 6-bit input 201 is Hi and the remaining bits are Lo, the 1-bit Hi output 203 outputs Hi and other outputs output Lo. Similarly, when an arbitrary bit of the 6-bit input 201 is Lo and the remaining bits are Hi, the 1-bit Lo output 204 outputs Hi and other outputs output Lo. When the decision circuit valid signal 202 is a Lo input, the all bits Lo 203 output outputs Hi and other outputs output Lo. In another input pattern, all outputs output Lo.

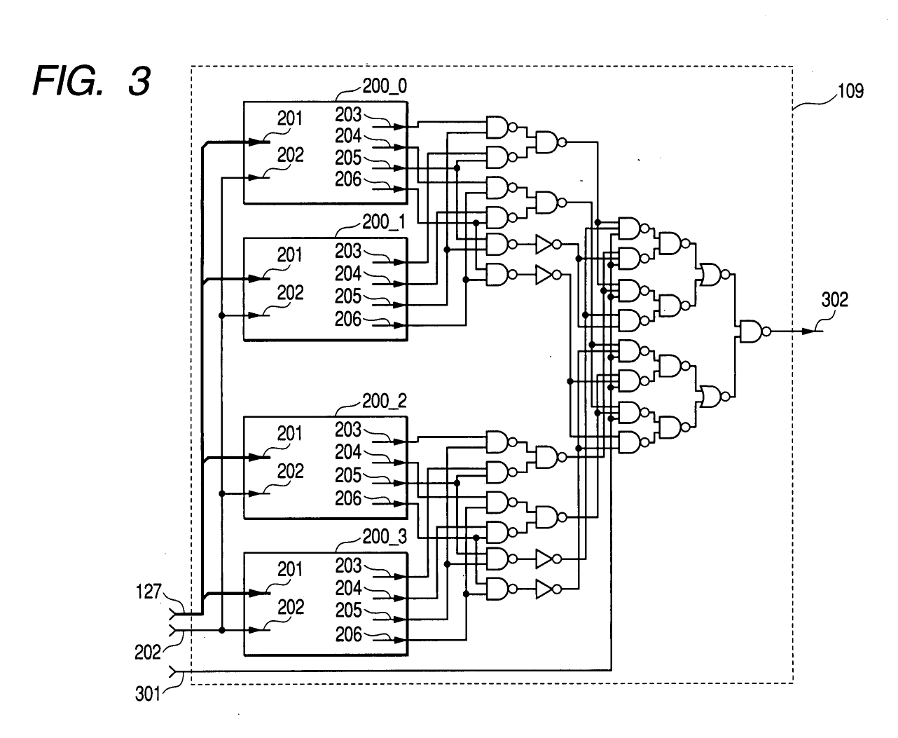

The 6-bit input parallel decision circuit 200 is used to design the parallel test decision circuit 109. FIG. 3 shows the detail of the parallel test decision circuit 109. The numeral 301 denotes an ECC relief valid signal; and the numeral 302, a parallel test decision result signal. The decision circuit valid signal 202 and the ECC relief valid signal 301 in FIG. 3 input a value written into the register 105, which is omitted in FIG. 1 for simplification.

When the decision circuit valid signal 202 is a Hi input, the parallel test decision circuit 109 decides coincidence/non-coincidence of the main amp output signal 127. When the decision circuit valid signal 202 is a Lo input, Hi is outputted regardless of the value of the main amp output signal 127. When the decision circuit valid signal 202 is Hi and the ECC relief valid signal 301 is Lo and all bits of the main amp output signal 127 are in coincidence, the parallel test decision result signal 302 outputs Hi. When even 1 bit of the main amp output signal 127 is non-coincident, the parallel test decision result signal 302 outputs Lo.

When the decision circuit valid signal 202 is Hi and the ECC relief valid signal 301 is Hi, a decision assuming relief in the ECC is performed. The main amp output signal 127 as a 24-bit signal of data 16 bits and parity 8 bits is divided into 12-bit signals of data 8 bits and parity 4 bits for each ECC relief unit. A first ECC relief unit has data bits 0 to 7 and parity bits 0 to 3, and a second ECC relief unit has data bits 8 to 15 and parity bits 4 to 7. Needless to say, the parallel test decision circuit 109 outputs Hi when all bits are in coincidence. When there is 1-bit non-coincidence in all bits, there is 2-bit non-coincidence in all bits and the respective non-coincident bits exist in another ECC relief unit, Hi is outputted. In another bit pattern, Lo is outputted.

The signal of the first ECC relief unit is inputted to the 6-bit input parallel decision circuits 200_0 and 200_1, and the signal of the second ECC relief unit is inputted to the 6-bit input parallel decision circuits 200_2 and 200_3. Decision is performed for each 6 bits. The decision results are summed in a combination circuit for outputting the parallel test decision result signal 302 as a final decision result. The pseudo independent parallel test will be described. In the above-described parallel test, since the same data is written into all bits in all mats, no defect depending on the data pattern can be detected. In the parallel test, data is read and written by the four test pins 130 of memory tester. This is used to test a bit pattern to some extent in the parallel test, which is the pseudo independent parallel test.

The pattern in which the four test pins 130 of memory tester are allocated to bits is the same as the parallel test except that at writing, writing is performed to only one mat and an arbitrary data pattern is inputted to each of the test pins 130 of the memory tester. At reading, the coincidence/non-coincidence of the bits allocated to the test pins 130 of memory tester is decided by the pseudo independent decision circuit 113. As compared with the case that the test pins 130 are connected to all the data pins 111, needless to say, the data pattern is limited. Any defect which has not been found in the parallel test can be selected.

When ECC relief decision is incorporated into the pseudo independent parallel test, a problem which has not been imposed in the parallel test, arises. For example, the bits allocated to the data pin 111_0 are data bits 0 to 3 and parity bits 0 to 1, and the bits allocated to the data pin 111_4 are data bits 4 to 7 and parity bits 2 to 3. Since different data may be written into the bits allocated to the data pin 111_0 and the bits allocated to the data pin 111_4, coincidence/non-coincidence must be decided individually. When 1-bit non-coincidence is decided as being accepted, a 2-bit defect may be decided as being accepted in the same ECC relief unit. A mechanism for avoiding this is necessary for the pseudo independent decision circuit 113.

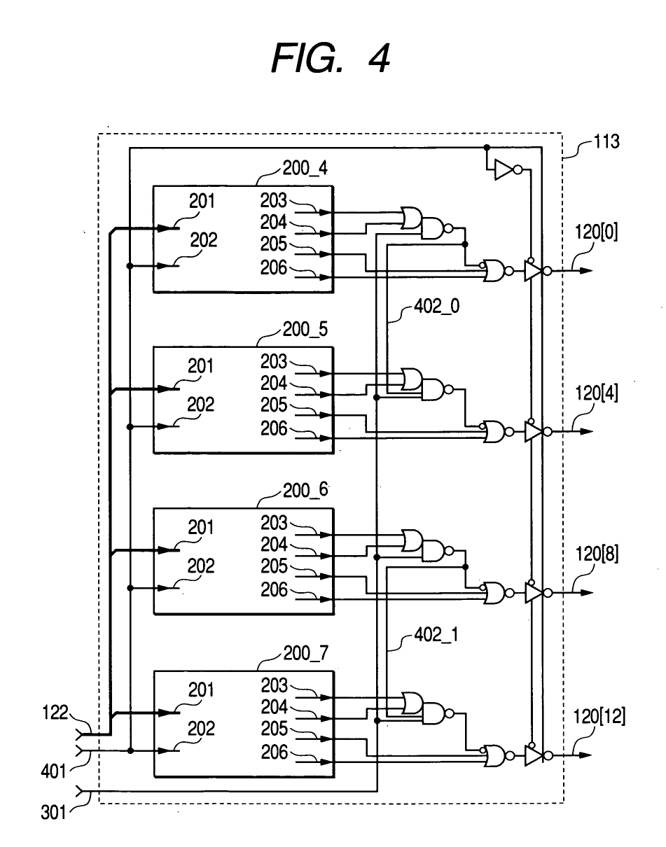

FIG. 4 shows a detailed diagram of the pseudo independent decision circuit 113. The numeral 401 denotes a pseudo independent decision circuit valid signal; and the numerals 402_0 and 402_1, a 1-bit defect decision signal. Data bits 0 to 3 and parity bits 0 to 1 of the global I/O bus 122 are inputted to the 6-bit input parallel decision circuit 200_4. Similarly, data bits 4 to 7 and parity bits 2 to 3 are inputted to the 6-bit input parallel decision circuit 200_5, data bits 8 to 11 and parity bits 4 to 5 are inputted to the 6-bit input parallel decision circuit 200_6, and data bits 12 to 15 and parity bits 6 to 7 are inputted to the 6-bit input parallel decision circuit 200_7.

When the pseudo independent decision circuit valid signal 401 is Lo, decision of coincidence/non-coincidence is not performed and all outputs are HiZ (high impedance). When the pseudo independent decision circuit valid signal 401 is Hi and the ECC relief valid signal 301 is Lo, the logical add of the all bits Hi decision output 206 and the all bits Lo decision output 205, which are decided in the 6-bit input parallel decision circuits 200_4 to 200_7, is outputted. That is, when all bits are in coincidence in the 6-bit input parallel decision circuits 200_4 to 200_7, the respective outputs output an acceptance decision.

When the pseudo independent decision circuit valid signal 401 is Hi and the ECC relief valid signal 301 is Hi, the operation is slightly complicated. The 6-bit input parallel decision circuit 200_4 and the 6-bit input parallel decision circuit 200_6 obtain the logical add of the 1-bit Hi decision output 203, the 1-bit Lo decision output 204, the all bits Lo output 205 and the all bits Hi output 206 for outputting it. All bits coincidence or 1-bit non-coincidence in 6 bits outputs an acceptance decision.

The output results of the 6-bit input parallel decision circuit 200_5 and the 6-bit input parallel decision circuit 200_7 are changed by the operation of the 6-bit input parallel decision circuit 200_4 and the 6-bit input parallel decision circuit 200_6. The 6-bit input parallel decision circuit 200_5 receives the 1-bit defect decision signal 402_0 from the 6-bit input parallel decision circuit 200_4.

When the 6-bit input parallel decision circuit 200_4 decides a 1-bit defect, 122[0] outputs an acceptance decision and at the same time, the 1-bit defect decision signal 402_0 is Lo. In this case, the 1-bit defect decision of the 6-bit input parallel decision circuit 200_5 is decided as being rejected. This can hold the limit of the 1-bit defect in the ECC relief units. The operations of the 6-bit input parallel decision circuits 200_6 and 200_7 are performed in the same manner to hold the limit of the 1-bit defect in the ECC relief units.

As the ECC relief unit of the ECC is increased, the number of parity bits can be reduced. For example, when structuring an ECC capable of correcting a 1-bit error to 128-bit data, 8 parity bits may be added. In a DRAM chip employing such ECC, one row address and column address specification is performed to output at least 128+8 bits as a main amp output from the memory mat. In the parallel test, the four mats need not be activated in parallel to complete the parallel test in one memory mat.

However, a problem arises when outputting the result of the parallel test to outside. As in the above embodiment, the redundancy relief is performed for each data 16 bits+parity and the test pins of the memory tester are connected to four data pins. In this case, only the test result for data 64 bits can be outputted for one access. Thus, 128+8 bits are tested twice.

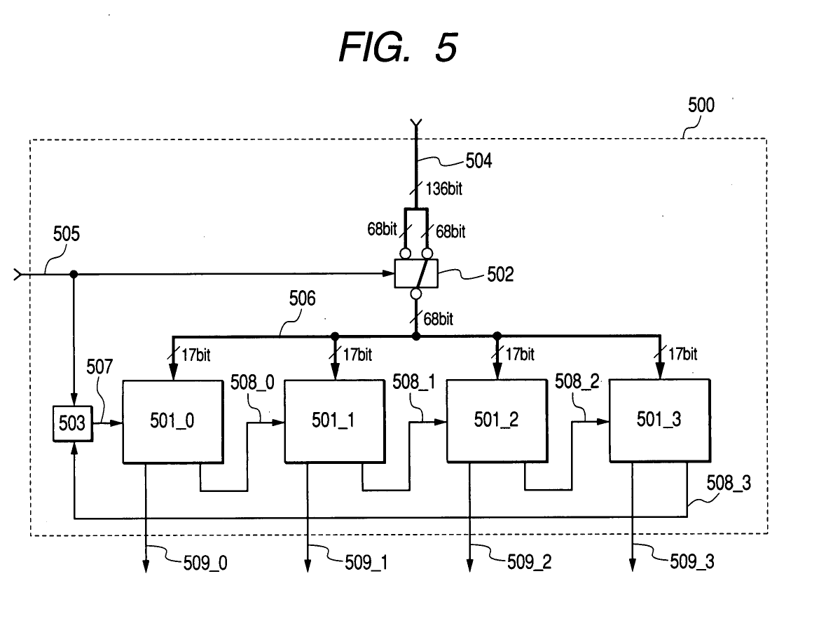

FIG. 5 shows a parallel test decision circuit 500 employing an ECC with 128+8 bits. The numerals 501_0 to 501_3 denote a 17-bit input parallel decision circuit; the numeral 502, a switching device; the numeral 503, a register; the numeral 504, a main amp output; the numeral 505, an address switch signal; the numeral 506, a parallel test input signal; the numeral 507, an register output; the numerals 508_0 to 508_3, a 1-bit defect flag; and the numeral 509, a test decision signal.

A parallel test conduction method when employing the ECC with 128+8 bits will be described in the following 1) to 5).

1) Parallel writing is not much different from the above one except that writing is performed to one mat in a 128+8 bit unit. To shorten the test time, writing is performed to four mats in parallel.

2) At reading, when a row address and a column address are specified, the main amp output 504 with 128+8 bits can be obtained. The least significant bit of the column address is inputted as the address switch signal 505 to the parallel test decision circuit 500. Here, 0 is assumed to be specified to the least significant bit of the column address for a first time. When the address switch signal 505 is 0, the register 503 is reset to output logic 0.

3) Since the address switch signal 505 is logic 0, the low-order 68 bits of the main amp output 504 are selected by the switching device 502 to be inputted to the 17-bit input parallel decision circuit 501 for each 17 bits.

4) When all 17 bits are in coincidence, the 17-bit input parallel decision circuit 501_0 outputs an acceptance decision to the test decision signal 509_0 regardless of the value of the register output 507. When there is 1-bit non-coincidence, the value of the register output 507 is referred. When the value of the register output 507 is logic 0, an acceptance decision is outputted to the test decision signal 509_0. When it is logic 1, a rejection decision is outputted thereto. When a defect with 2 bits or more occurs, a rejection decision is outputted to the test decision signal 509_0 regardless of the value of the register output 507. Logic 1 is outputted to the 1-bit defect flag output 508_0 when the register output 507 is logic 1. In the case of the 1-bit defect, logic 1 is also outputted thereto. In the case of other than that, logic 0 is outputted thereto.

5) The 17-bit input parallel decision circuits 501_1 to 501_3 decide acceptance or rejection while referring to the 1-bit defect flag outputs 508_0 to 508_2 in the previous stage. The 1-bit defect output of the 17-bit input parallel decision circuit 501_3 is stored in the register output 507 and is outputted when the address switch signal 505 is switched to logic 1.

6) The least significant bit of the column address is switched to 1. At this time, the main amp is not operated. When the address switch signal 505 is 1, the high-order 68 bits of the main amp output 504 are selected by the switching device 502 to be inputted to the 17-bit input parallel decision circuit 501 for each 17 bits.

7) The acceptance/rejection decision is performed as in the case that the address switch signal 505 is logic 0. Only in the decision of the 17-bit input parallel decision circuit 501_0, the value of the 1-bit defect flag 508_3 when the address switch signal 505 is logic 0 is stored in the register. The acceptance/rejection decision is performed according to the value.

8) As described above, the 1-bit defect flags 508 are transmitted sequentially to the next stage. The condition that only a 1-bit defect is allowed in 128+8 bits is held. In such method, the possibility that the 1-bit defect may be allowed or redundancy-relieved is unbalanced. The possibility that a plurality of 1-bit defects may occur in 128+8 bits is low, which is not substantially a problem.

In summary, the following is described. When an ECC relief unit n is smaller than a redundancy relief unit m and a parallel test decision unit p (n<m and n<p), decision is performed under the condition that a 1-bit defect is allowed for each ECC unit. According to this, the acceptance/rejection decision of the redundancy relief unit is performed. On the contrary, when the ECC relief unit n is larger than the redundancy relief unit m or the parallel test decision unit p (n>m or n>p), all bits acceptance, a 1-bit defect or a defect with 2 bits or more is decided in each redundancy relief unit or parallel test decision unit, and when a 1-bit defect is detected in another location, the decision result is outputted so that the number of defects in the ECC relief unit will not exceed 1 bit. When the ECC relief unit is across a plurality of addresses, a 1-bit defect flag may be stored in the register for reference in the acceptance-rejection decision in another address.

In the above embodiments, the ECC corrects a 1-bit defect. Depending on the ECC structuring method, a defect with 2 bits or more can be corrected. An ECC capable of correcting an m-bit defect is employed to perform decision in such a manner that an n-bit defect is decided as a non-defective product in the ECC relief unit (m≧n). Also in this case, the basic idea is the same as above and the decision of 1-bit non-coincidence as being accepted may be changed to the decision of n-bit non-coincidence as being accepted. When the ECC relief unit n is larger than the redundancy relief unit m or the parallel test decision unit p, a 1-bit defect flag may be extended to a plurality of bits for multiplication by the number of defective bits, thereby changing the decision result so as not to exceed n.

In this embodiment, response to the ECC is processed in the DRAM chip, and when viewed from outside, this case is not different from the case of the absence of the ECC. The output of the DRAM is tri-state. Generally, the memory tester can decide tri-state. The all bits acceptance may be a Hi output, the 1-bit defect may be a HiZ output (high impedance output), and the defect with 2 bits or more may be a Lo output. How the redundancy relief is performed may be left to the program of the outside.

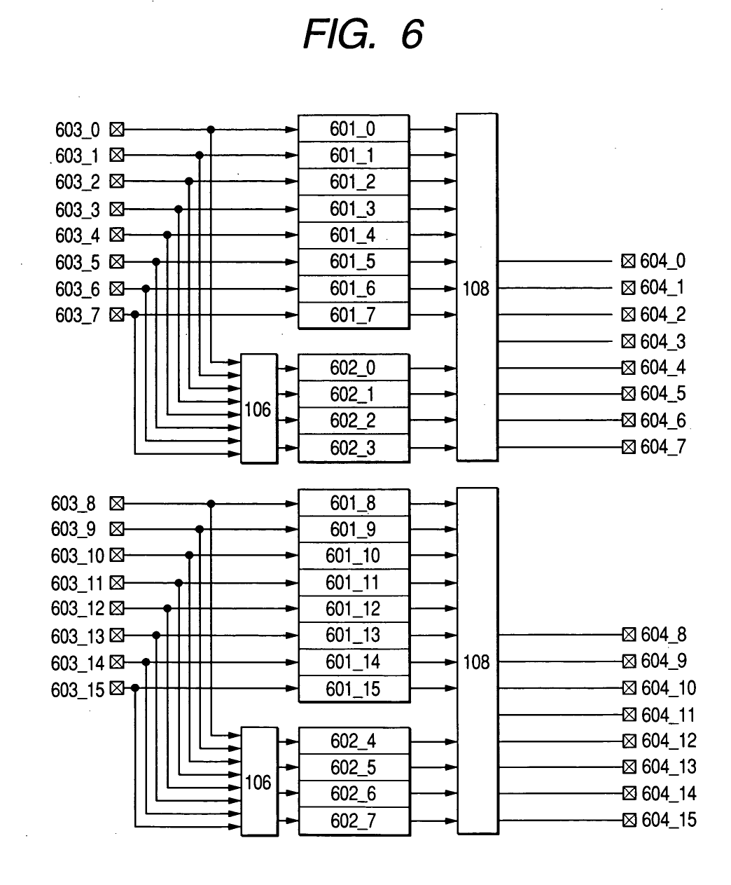

The above description is mainly about the parallel test. The parallel test selects defective chips before shipping. When checking any design mistakes, a more detailed test must be conducted. When employing the ECC, any inside defect is hidden so as to inhibit the check of any design mistakes. It is convenient that the DRAM employing the ECC can operate data bits and parity bits not via the ECC. To simplify the later discussion, a basic data flow will be described according to FIG. 6.

FIG. 6 shows a data flow. It should be noted that it is not always in coincidence with actual signal line connection. Input data 603_0 to 603_15 are inputted to be stored in memory cells 601_0 to 601_15. Based on the input data 603_0 to 603_15, the parity generation circuit generates parity to store it in memory cells 602_0 to 602_7.

In data reading, error correction is performed in the ECC decoders 108 from the data and parity stored in the memory cells 601_0 to 601_15 and 602_0 to 602_7 for outputting output data 604_0 to 604_15.

It should be noted that the parity stored in the memory cells 602_0 to 602_7 is internally generated by the parity generation circuit 106, which is not controllable. Error correction of the memory cells 601_0 to 601_15 and 602_0 to 602_7 is performed in the ECC decoders 108, which is not observable. The check of the internal circuits is thus very difficult. To avoid this, all memory cells are allowed to be controllable and observable. To allow the memory cells for data 601_0 to 601_15 to be observable, the ECC decoders 108 do not perform error correction, which is a technique typically used.

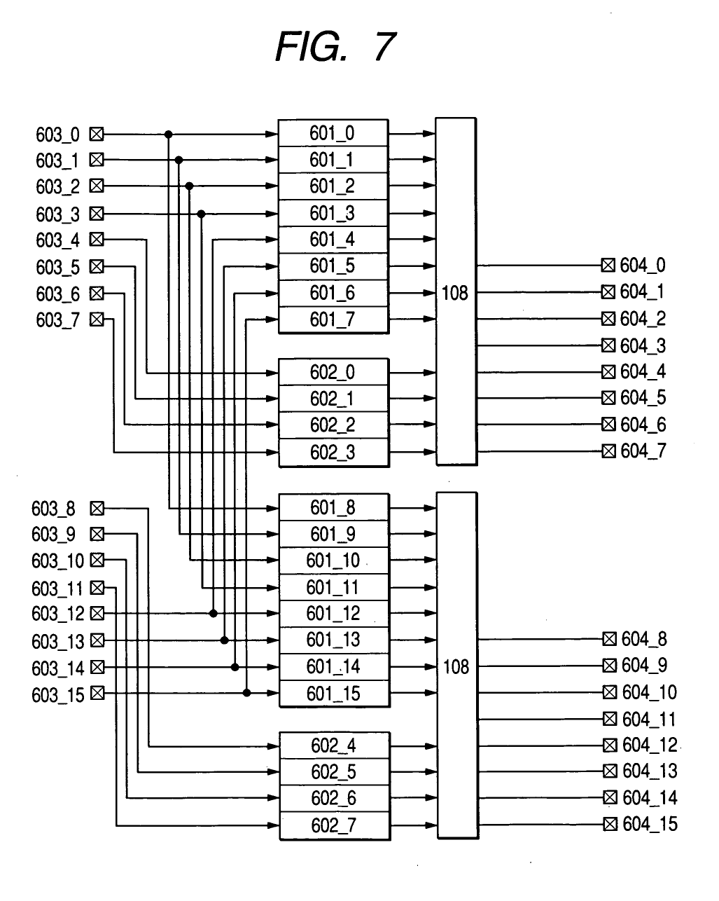

To allow the memory cells for parity 602_0 to 602_7 to be controllable, signal line connection as shown in FIG. 7 is performed. The inputs 603_4 to 603_11 are allocated to the memory cells for parity 602_0 to 602_7. This can be performed by a general memory device employing the ECC. The connection is further contrived. The memory cells for parity 602_0 to 602_7 are connected to the inputs 603_4 to 603_11 so that the memory cells for data 601_4 to 601_11 are brought into the state of Don't care. Generally, the inputs 603_4 to 603_11 remain connected or no data is written into the memory cells for data 601_0 to 601_15.

In the present invention, the inputs 603_12 to 603_15 are allocated to the memory cells for data 601_4 to 601_7. The inputs 603_0 to 603_3 are allocated to the memory cells for data 601_8 to 601_11. Thus, an arbitrary bit pattern can be allocated to the memory cells 601_0 to 601_7+602_0 to 602_3 in the ECC relief unit. The memory cells 601_8 to 601_15+602_4 to 602_7 are similar. This can arbitrarily give an input to the ECC decoders 108, thereby making the debug operation efficient. The data connection change is performed in the parallel test selector in FIG. 1.

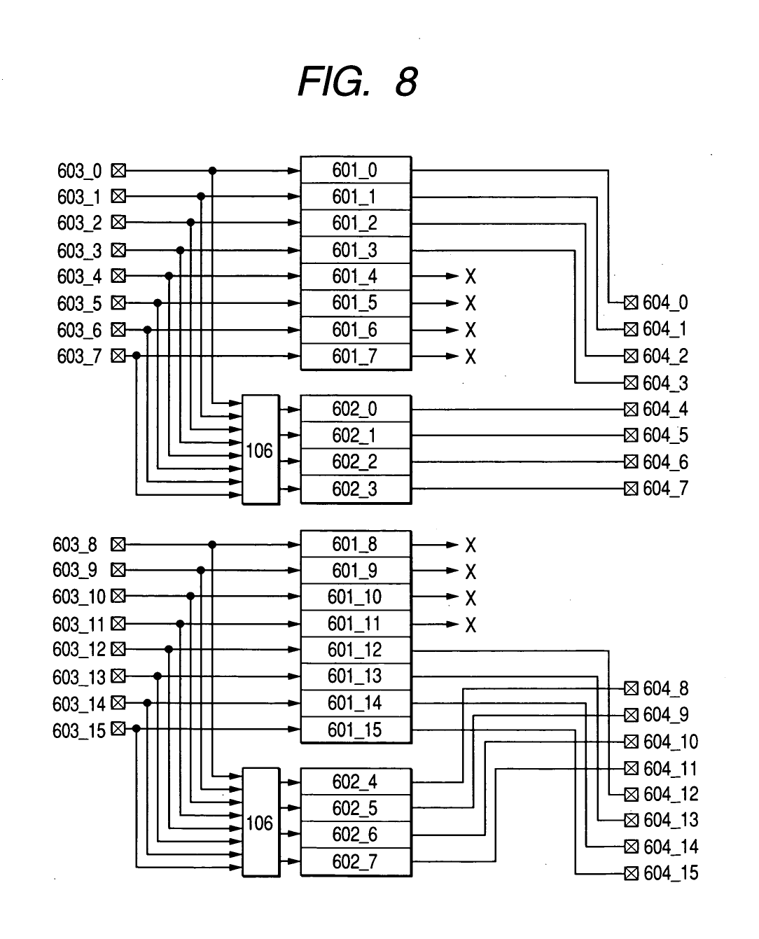

To allow the memory cells for parity 602_0 to 602_7 to be observable, signal line connection as shown in FIG. 8 is performed. The memory cells for parity 602_0 to 602_7 are connected to the outputs 604_4 to 604_11. The memory cells for data 601_0 to 601_3 are connected to the outputs 604_0 to 604_3. The memory cells for data 601_12 to 601_15 are connected to the outputs 604_12 to 604_15.

To the memory cells for parity 602_0 to 602_7 to be observable, they may simply be connected to the outputs. Not only the memory cells for parity but also the memory cells for data are connected to the outputs from the following reasons. The input side of the connection method for allowing the memory cells for parity 602_0 to 602_7 to be controllable, which is shown in FIG. 7, and the output side of the connection method for allowing the memory cells for parity 602_0 to 602_7 to be observable, are used in parallel. The DRAM can be regarded as a DRAM not employing the simple ECC. This means that the program of the memory tester for checking the memory cells need not be changed. The debug operation can be significantly efficient.

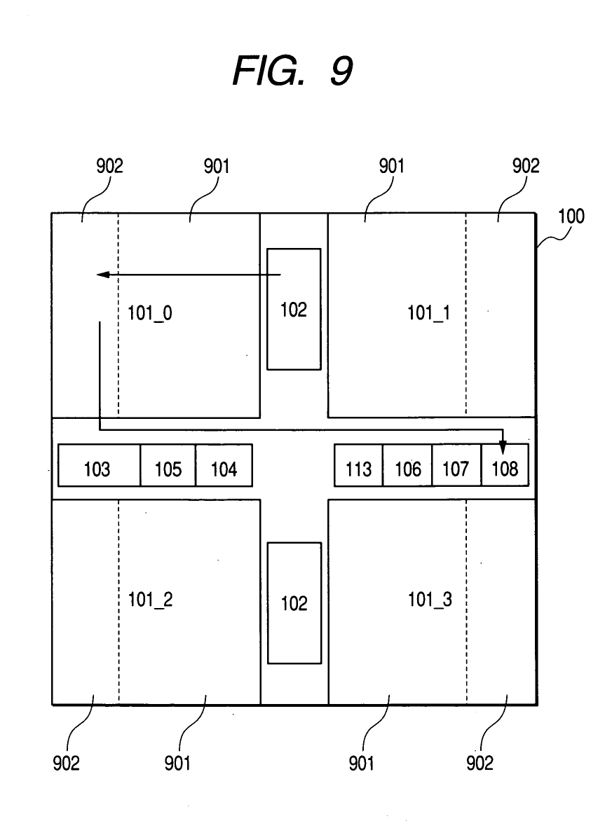

FIG. 9 shows a layout example of the DRAM chip 100. The memory arrays 101_0 to 101_4 are arranged in four corners and peripheral circuits are arranged in the middle portion, as shown in FIG. 9, which is the basic of the DRAM chip design. They are so arranged that the data flow at reading of the DRAM chip 100 is as shown by the arrows in FIG. 9.

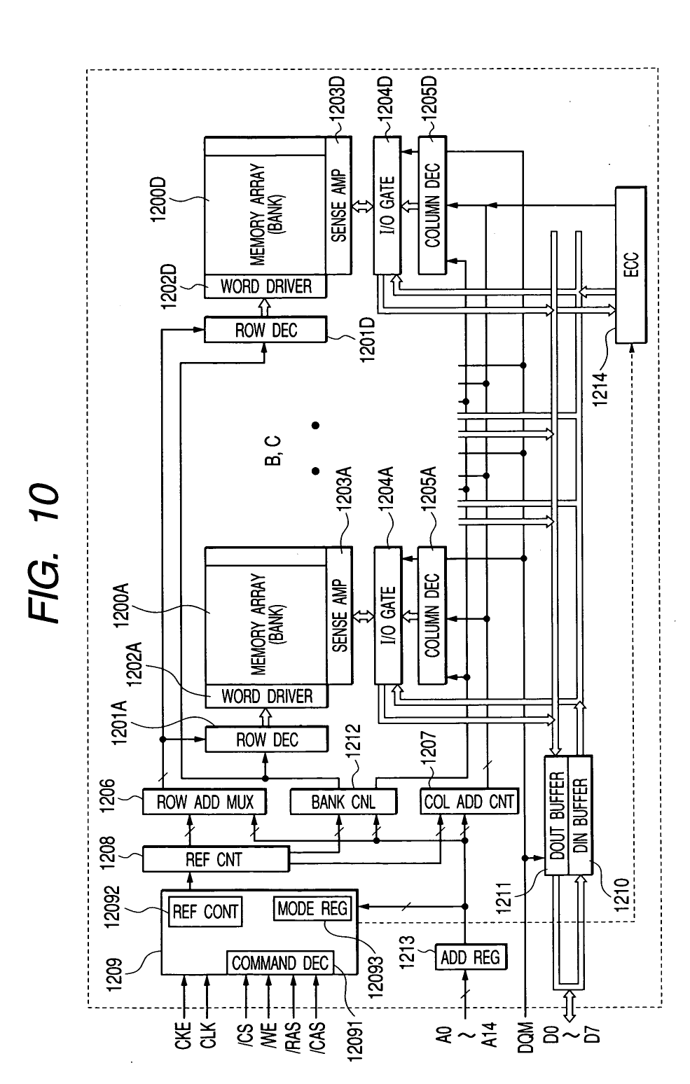

Since the DRAM chip 100 employs the ECC, lowered speed at reading becomes a problem. The memory arrays 101_0 to 101_4 are divided into data parts and parity parts to arrange parity in the positions in which the data flow is slow. In the example of FIG. 9, data is arranged in parts 901 and parity is arranged in parts 902. The algorithm of the ECC is omitted. The critical path in the ECC is the data flow. The access speed is not lowered when parity is slightly late. This arrangement increases the entire access speed. In this example, the memory arrays 101_0 to 101_4 are divided into the left and right sides. Regardless of the division method, data speed-dependent is apparent. FIG. 10 shows an overall block diagram of an embodiment of a dynamic RAM (hereinafter, simply called a DRAM) according to the present invention. The DRAM of this embodiment is intended for an SDRAM (Synchronous Dynamic Random Access Memory). Not being particularly limited, the SDRAM of this embodiment is provided with four memory arrays (MEMORY ARRAYs) 1200A to 1200D corresponding to four memory banks (BANKs). In the drawing, the two memory arrays 1200A and 1200D of them are representatively exemplified. The memory arrays 1200A to 1200D corresponding to the four memory banks 0 to 3 have dynamic memory cells arranged in a matrix, respectively. The select terminals of the memory cells arranged vertically in the memory array in the drawing are connected to word lines, not shown, and the data input/output terminals of the memory cells arranged horizontally therein are connected to complementary data lines, not shown, for each row.

One word line, not shown, of the memory array 1200A is driven at the select level according to the decode result of the row address signal of the row decoder (ROW DEC) 1201A. The row decoder 12001A includes a word driver (WORD DRIVER) for the select level of one word line according to the decode result. The complementary data line, not shown, of the memory array 1200A is connected to an input/output line (IO line) by a sense amp (SENSE AMP) 1203A, an IO gate circuit (I/O GATE) 1204A as a column select circuit, and a column decoder (COLUMN DEC) 1205A. The IO gate includes a main amp and a write amp.

The sense amp 1202A is an amplification circuit for detecting and amplifying a small potential difference which appears the respective complementary data lines by data read from the memory cells. The IO gate circuit 1204A includes switch MOSFETs for selecting the respective complementary data lines to be made conductive to the complementary I/O lines. The column switch MOSFET is selectively operated by the decode result of the column address signal of the column decoder 1205A. Similarly, the memory arrays 1200B to 1200C, not shown, are provided with row decoders 1201B to 1201C, sense amps 1203B to 1203C, IO gate circuits 1203B to 1203C and column decoders 1205B to 1205C. The I/O line is shared among the memory banks and is connected to the output terminal of a data input circuit (DIN BUFFER) 1210 and the input terminal of a data output circuit (DOUT BUFFER) 1211. Not being particularly limited, terminals D0 to D7 are data input/output terminals for inputting or outputting 8-bit data D0 to D7.

Address signals A0 to A14 supplied from the address input terminals are once held by an address register (ADD REG) 1213. The row address signals for selecting the memory cell of the address signals chronologically inputted are supplied via a row address multiplexer (ROW ADD MUX) 1206 to the row decoders 1201A to 1201D of the memory banks. The A13 and A14 as the address signals for selecting the memory bank are allocated and are supplied to a bank control (BANKCNL) circuit 1212 to form select signals of the four memory banks. The column address signals are held by a column address counter (COLUMN ADD CNT) 1207. A refresh counter (REF CNT) 1208 generates a row address at Automatic Refresh and a row address and a column address at Self Refresh.

With a 256-Mbit memory capacity, up to the column address signals A10 is valid in an 8-bit structure. The column address signals chronologically inputted are supplied as preset data to the column address counter 1208. The column address signals as the preset data in burst mode specified by the later-described command or values obtained by sequentially incrementing the column address signals are outputted to the column decoders 1205A to 1205D of the memory banks.

A control logic (CONTROL LOGIC) 1209 has a command decoder (COMMAND DEC) 12091, a refresh control (REF CONTROL) 12092 and a mode register (MODE REG) 12093. The mode register 12092 holds various kinds of pieces of operation mode information. Only one corresponding to the bank specified by the bank control circuit 1212 of the row decoder 1201A to 1201D is operated to perform word line select operation.

Not being particularly limited, the control circuit 1209 to which external control signals such as clock signal CLK, clock enable signal CKE, chip select signal /CS (The symbol / means that a signal given it is a row enable signal.), column address strobe signal /CAS, row address strobe signal /RAS and write enable signal /WE, DQM and the address signals via the mode register 12093 are supplied, forms an internal timing signal for controlling the operation mode of the SDRAM and the operation of the circuit blocks based on change in level and timing of the signals, and has an input buffer corresponding to the signals.

Other external input signals are significant in synchronization with the rising edge of the internal clock signal. The chip select signal /CS instructs the start of the command input cycle by its low level. When the chip select signal /CS at high level (chip unselected state), other inputs are invalid. The later-described internal operation such as the selected state of the memory bank or burst operation is not affected by the change to the chip unselected state. The respective signals /RAS, /CAS and /WE have a function different from that of the corresponding signal in a typical DRAM and are significant signals for the later-described command cycle definition.

The clock enable signal CKE is a signal instructing the validity of the next clock signal. When the signal CKE is at high level, the rising edge of the next clock signal CLK is valid. When it is at low level, it is invalid. In read mode, when provided with an external control signal /OE for controlling output enable to a data output circuit 1211, the signal /OE is supplied to the control circuit 1209. When the signal is at high level, the data output circuit 1211 is brought into a high output impedance state.

The row address signal is defined by the levels of A0 to A12 in row address strobe and bank active command cycle in synchronization with the rising edge of the clock signal CLK (internal clock signal).

The address signals A13 and A14 are regarded as bank select signals in the row address strobe and bank active command cycle. That is, a combination of the A13 and A14 selects one of the four memory banks 0 to 3. Not being particularly limited, the select control of the memory banks can be done by the processing of activation of only the row decoder on the selected memory bank side, non-selection of all column switch circuits on the unselected memory bank side, and connection of the data input circuit 1210 and the data output circuit only on the selected memory bank side.

In the SDRAM, when the burst operation is performed in one memory bank, another memory bank is specified to supply a row address strobe and bank active command, the row address operation in the another memory bank is enabled without affecting the one memory bank during execution. Unless a collision among the data D0 to D7 occurs in an 8-bit data input/output terminal, a precharge command and a row address strobe and bank active command to a memory bank different from the memory bank processed by the command during execution are issued during the execution of the command whose processing has not been ended, thereby starting the internal operation.

An internal power generation circuit, not shown, is provided to generate various internal voltages such as an internal rising voltage VPP corresponding to the select level of the word line upon reception of an operation voltage such as VCC and VSS supplied from the power terminal, an internal dropping voltage VDL corresponding to the operation voltage of the sense amp, an internal dropping voltage VPERI corresponding to the operation voltage of the peripheral circuit, a plate voltage of the memory cell, not shown, a precharge voltage such as VDL/2, and a substrate back bias voltage VBB.

In the DRAM of this embodiment, an ECC circuit 1214 as described above is provided in the DRAM chip. The ECC circuit 1214 is shared among the four memory banks 1200A to 1200D. A check bit is generated to write data inputted from the input circuit 1210 to be written into the selected memory bank with the write data. At the reading operation, the data and check bit are read from the selected memory bank to output, via the output circuit 1211, data in which error detection correction has been performed.

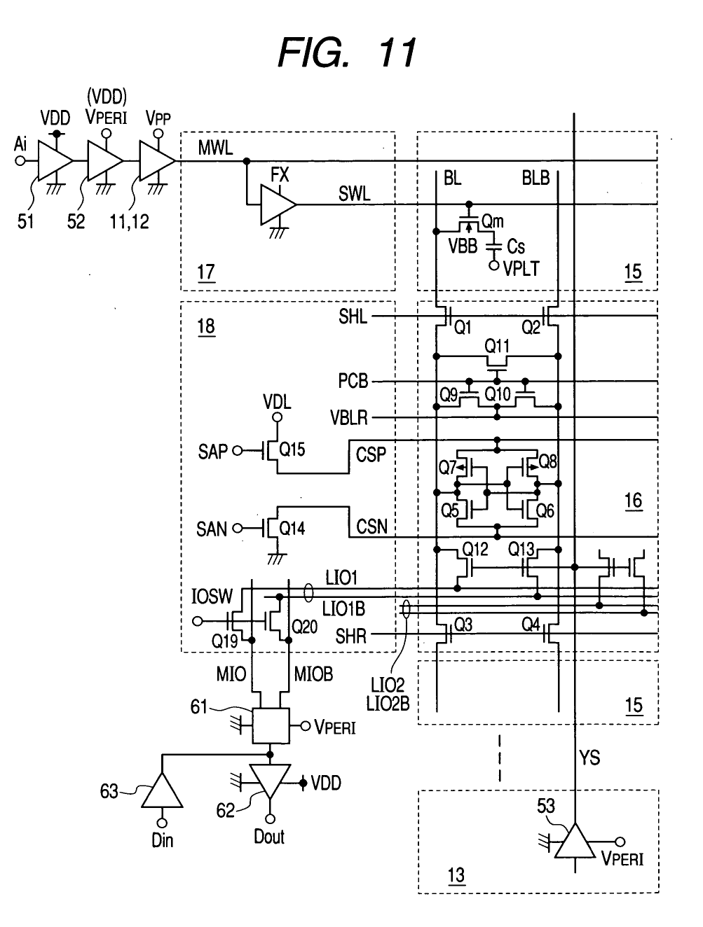

FIG. 11 shows a circuit diagram of an embodiment of a DRAM according to the present invention. In the drawing, with the sense amp part as the middle, a circuit diagram simplifying address input to data output is illustrated. In this embodiment, a pair of complementary bit lines are returned at the sense amp as the middle to be extended in parallel, which is a so-called 2-cross point method. In the drawing, there are provided hierarchical structures so that the word line consists of a main word line MWL and a sub word line SWL and the input/output line consists of a local input/output line LIO and a main input/output line MIO. A circuit provided on a sense amp 16 and a cross area 18 so as to be vertically interposed between two sub arrays 15 is illustrated. Others are shown as a block diagram.

One dynamic memory cell provided between the sub word line SWL provided in the one memory mat 15 and one bit line BL of complementary bit lines BL and BLB is representatively illustrated. The dynamic memory cell has an address select MOSFET Qm and a memory capacitor Cs. The gate of the address select MOSFET Qm is connected to the sub word line SWL, the drain of the MOSFET Qm is connected to the bit line BL, and the source thereof is connected to the memory capacitor Cs. The other electrode of the memory capacitor Cs is shared and is given the plate voltage VPLT. The negative back bias voltage VBB is applied to the substrate (channel) of the MOSFET Qm. Not being particularly limited, the back bias voltage VBB is set to a voltage of −1V. The select level of the sub word line SWL is the high voltage VPP which is higher by the threshold voltage of the address select MOSFET Qm than the high level of the bit line.

When the sense amp is operated by the internal dropping voltage VDL, the high level amplified by the sense amp to be given to the bit line is at the internal voltage VDL level. The high voltage VPP corresponding to the select level of the word line is VDL+Vth+α. A pair of the complementary bit lines BL and BLB of the sub array provided on the left side of the sense amp are arranged in parallel, as shown in the drawing. The complementary bit lines BL and BLB are connected to the input/output nodes of the unit circuit of the sense amp by shared switch MOSFETs Q1 and Q2.

The unit circuit of the sense amp is constructed by a CMOS latch circuit having N-channel amplification MOSFETs Q5 and Q6 and P-channel amplification MOSFETs Q7 and Q8, which is in a latch form by cross-connecting the gates and the drains. The sources of the N-channel MOSFETs Q5 and Q6 are connected to common source line CSN. The sources of the P-channel MOSFETs Q7 and Q8 are connected to common source line CSP. The common source lines CSN and CSP are connected to power switches MOSFETs, respectively.

Not being particularly limited, the common source line CSN connected to the sources of the N-channel amplification MOSFETs Q5 and Q6 is given an operation voltage corresponding to the ground potential by an N-channel power switch MOSFET Q14 provided in the cross area 18. The common source line CSP connected to the sources of the P-channel amplification MOSFETs Q7 and Q8 is provided with an N-channel power MOSFET Q15 for supplying the internal voltage VDL. The power switch MOSFETs may be provided to be distributed in the unit circuits. Activating signals for sense amp SAN and SAP supplied to the gates of the N-channel power MOSFETs Q14 and Q15 are signals in the same phase which are at high level at activation of the sense amp. The high level of the signal SAP is a signal at the rising voltage VPP level. The rising voltage VPP is about 3.6V when the VDL is 1.8V. The N-channel MOSFET Q15 is sufficiently brought into the on state to allow the common source line CSP to be at the internal voltage VDL level.

The input/output nodes of the unit circuit of the sense amp are provided with a precharge (equalize) circuit having a equalize MOSFET Q11 for short-circuiting the complementary bit lines, and switch MOSFETs Q9 and Q10 for supplying a half precharge voltage VBLR to the complementary bit lines. A precharge signal PCB is sharably supplied to the gates of the MOSFETs Q9 to Q11. A driver circuit for forming the precharge signal PCB is provided with an inverter circuit, not shown, in the cross area to make the rising or falling faster. Prior to the word line select timing at the start of the memory access, the MOSFETs Q9 to Q11 constructing the precharge circuit are switched at high speed via the inverter circuits distributed in the cross areas.

An IO switch circuit IOSW (switch MOSFETs Q19 and Q20 for connecting the local input/output line LIO and the main input/output line MIO) is placed on the cross area 18. As described above, there are also provided a half precharge circuit of the common source lines CSP and CSN of the sense amp, a half precharge circuit of the local input/output line LIO, a VDL precharge circuit of the main input/output line, and a distribution driver circuit of shared select signal lines SHR and SHL.

The unit circuit of the sense amp is connected via shared switch MOSFETs Q3 and Q4 to the similar complementary bit lines BL and BLB of the sub array 15 on the lower side of the drawing. For example, when the sub word line SWL of the sub array on the upper side is selected, the upper-side shared switches MOSFETs Q1 and Q2 of the sense amp are brought into the on state, and the lower-side shared switch MOSFETs Q3 and Q4 are brought into the off state. The switch MOSFETs Q12 and Q13 construct a column (Y) switch circuit. When the select signal YS is at the select level (high level), it is brought into the on state to connect the input/output nodes of the unit circuit of the sense amp to the local input/output lines LIO1 and LIO1B, LIO2 and LIO2B.

The input/output nodes of the sense amp are connected to the upper-side complementary bit lines BL and BLB, amplifies the small signal of the memory cell connected to the selected subword line SWL, and transmits it via the column switch circuits (Q12 and Q13) to the local input/output lines LIO0 and LIO1B. The local input/output lines LIO0 and LIO1B are extended along the sense amp column, that is, horizontally in the drawing. The local input/output lines LIO0 and LIO1B are connected via the IO switch circuit having the N-channel MOSFETs Q19 and Q20 provided in the cross area 18 to the main input/output lines MIO and MIOB connected to the input terminals of a main amp 61.

The IO switch circuit is switch-controlled by the select signal formed by decoding an X address signal. The IO switch circuit may have a CMOS switch structure in which the N-channel MOSFETs Q19 and Q20 are connected in parallel to the P-channel MOSFETs, respectively. In the burst mode of the synchronous DRAM, the column select signal YS is switched by counter operation to sequentially switch connections of the local input/output lines LIO0 and LIO1B, and LIO2 and LIO2B to two pairs of the complementary bit lines BL and BLB of the sub arrays. An address signal Ai is supplied to an address buffer 51. The address buffer is operated in time division to fetch an X address signal and a Y address signal. The X address signal is supplied to a predecoder 52 to form a select signal of the main word line MWL via a main row decoder 11 and a main word driver 12. The address buffer 51 receives the address signal Ai supplied from the external terminal and is operated by the source voltage VDD (or VCC) supplied from the external terminal. The predecoder is operated by the dropping voltage VPER1 dropping it. The main word driver 12 is operated by the rising voltage VPP. As the main word driver 12, a logic circuit with a level conversion function for receiving the predecode signal is used. A column decoder (driver) 53 includes a driving circuit in which an operation voltage is formed by a MOSFET Q23 constructing the VCLP generation circuit, and receives the Y address signal supplied by the time division operation of the address buffer 51 to form the select signal YS.

The main amp 61 is operated by the dropping voltage VPERI and is outputted from an external terminal Dout via an output buffer 62 operated by the source voltage VDD supplied from the external terminal. The write signal inputted from an external terminal Din is fetched via an input buffer 63 to supply the write signal via the write amp (write driver) included in the main amp 61 in the drawing to the main input/output lines MIO and MIOB. The input part of the output buffer 62 is provided with a level conversion circuit and a logic part for outputting its output signal in synchronization with a timing signal corresponding to the clock signal.

As the main memory device of a computer system, a dynamic random access memory (DRAM) using a semiconductor is generally used. As compared with other semiconductor memory devices, the DRAM has a high integration degree and can read and write information relatively fast. As the problem of the DRAM, however, memory holding time is very short (typically, about tens of ms to 1s) so that memory updating operation called refresh must be frequently performed. Since reading and writing of information cannot be done during the refresh operation, the refresh operation limits the speed for reading and writing information in the DRAM.

Basically, the information position in the DRAM is specified by the row address and the column address. When the integration degree of the DRAM rises by one generation, the row address is double, the column address is double and the capacity is four times. The refresh of the memory is performed by row address specification. For each generation rise, the number of times of refresh is double. In the prior art, for each generation rise, a refresh interval tREF is twice to hold the time for refresh per unit time constant. The refresh time per unit time is called a busy factor (γ) and is shown by Equation 1.

$$γ = \frac{tRC min x n}{tREF} \qquad [ Equation 1 ]$$

The increase in the integration degree of the DRAM means that the area of the memory cell used for holding memory is reduced. When the memory cell is reduced, the capacity of the capacitor is reduced. Basically, the memory holding time is shortened. The capacity of the capacitor has been attempted to be increased by making the memory cells three-dimensional (stacked capacitor or trench capacitor), thinning of an insulating film and use of a high dielectric material).

The making of the memory cells three-dimensional will increase the cost due to the complicated process. The thinning of an insulating film will drastically increase a leakage current due to the electron quantum effect when the thinning is excessively done. The excessive thinning provides an adverse effect. The kinds of high dielectric materials applicable to the semiconductor process are limited, making it difficult to use.

From these reasons, the tREF is being difficult to increase year by year. In fact, while the tREF standards of a 64-Mbit SDRAM is 64 ms, the tREF standards of a 256-Mbit SDRAM is 64 ms. As described above, to prevent the busy factor from being deteriorated, the tREF must be double in generational change. On this trend, the tREF of the 256-Mbit SDRAM should be 128 ms. It can be assumed from this that an attempt to increase the tREF is being limited.

The refresh interval is longer in excess of the tREF, which does not mean that all memory cells cannot hold memory in parallel. The number of defective bits is gradually increased due to an error with several bits in one chip. The error with several bits can be hidden so that the tREF can be substantially increased.

An SDRAM and a DDR SDRAM (DDR: Double Data Rate) as currently major DRAM products are called an 8-pin chip in which 8 information input/output terminals exist. A 4-bit check bit is added to 8-bit information and the ECC for correcting a 1-bit error in 12 bits (8+4 bits) is mounted to substantially increase the tREF. The memory cells limiting the tREF whose memory holding time is short exist relatively scatteringly. The possibility that the memory cells whose memory holding time is short for 2 bits or more in the 12 bits may exist is very low. As described above, the tREF is easy to increase.

In the present invention described above, 1) in the parallel test, not only all bits coincidence but also 1-bit non-coincidence is decided as being accepted. The parallel test assuming to relieve any defective bits by the ECC can be conducted. 2) When executing the test for writing data directly from outside into parity bits, data is allocated not only to parity bits but also to data bits to easily execute the test of the ECC decoder. 3) When executing the test for directly reading parity bits, allocation of parity bits and data bits is the same as the test writing data directly from outside into parity bits. At the check of parity bits, operation can be done as a general DRAM. 4) In the arrangement in the memory array, parity bit areas are arranged in the areas in which the reading time is slower than data areas. The access speed of the entire DRAM chip can be increased.

The inventions which have been made by the present inventors are specifically described above based on embodiments. The present invention is not limited to the above embodiments and various modifications can be made without departing from its purpose. For example, the ECC structure is not limited to 8+4 and various methods such as 16+5, 32+6 or 64+7 can be considered. The basic idea is disclosed by this patent. In the parallel test, the same data is written into all bits. There is also the case that a data pattern generated in a chip is written, and at reading, acceptance or rejection is decided as compared with the data pattern generated in the chip. Also in this case, the basic idea of the present invention in which 1-bit non-coincidence is decided as being accepted is not changed and can be applied. The present invention can be widely used in a semiconductor memory device in which writing and reading are performed like a DRAM, a static RAM and a nonvolatile memory device such as a flash memory and a test method thereof.

The effects obtained by the representative inventions disclosed in the present invention will be simply described as follows. A semiconductor memory device has an ECC circuit capable of correcting, from an m-bit information code and an n-bit check code stored in an information storing part, an error of the information code to x bits, and a parallel test circuit for receiving an information code and a check code for test with the same bits stored in the information storing part and deciding a defect with the x+1 bits or more as being defective. It is possible to obtain a semiconductor memory device mounting the ECC which enables an efficient test with high accuracy by a simplified structure.

A test method of a semiconductor memory device having an ECC circuit capable of correcting, from an m-bit information code and an n-bit check code stored in an information storing part, an error of the information code to x bits and a test circuit for receiving an information code and a check code in the information storing part, wherein an information code and a check code for test with the same bits are stored in the information storing part, the stored information code and check code for test are transmitted to the test circuit, and a defect with the x+1 bits or more for one piece of position information is decided as being defective. An efficient test is enabled with high accuracy by a simplified structure.

What is claimed is:

1. A semiconductor memory device comprising:
an information storing part for storing an m-bit information code and an n-bit check code for one piece of position information;
an ECC circuit capable of correcting, from an information code and a check code stored in said information storing part, an error of said information code to x bits; and
a parallel test circuit for receiving an information code and a check code for test with the same bits stored in said information storing part and deciding a defect with said x+1 bits or more for one piece of position information as being defective.

2. The semiconductor memory device according to claim 1,
wherein a plurality of said information storing parts are accessible individually,
wherein a plurality of said parallel test circuits are provided corresponding to said plurality of information storing parts, respectively,
wherein said ECC circuit is provided to be shared among said plurality of information storing parts, and
wherein said plurality of information storing parts store an information code and a check code for test in the same pattern, said plurality of parallel test circuits are valid in parallel in test mode, each deciding a defect with said x+1 bits or more as being defective for outputting individually.

3. The semiconductor memory device according to claim 1, further comprising:
a z-bit information input/output terminal in which the relation of z>n is established; and
a write signal path in which at information input in test mode, an information input terminal with n bits of z bits is used to be written as an n-bit check code into said information storing part and an information input/output terminal with the remaining z-n bits or less is used to be written thereinto as an information code of said information storing part.

4. The semiconductor memory device according to claim 3, further comprising a read path in which an information code and a check code stored in said information storing part are used for reading in test mode corresponding to allocation of said information code and check code to the information input/output terminal, used at said information input in test mode.

5. A semiconductor memory device comprising:
an information storing part for storing an m-bit information code and an n-bit check code for one piece of position information; and
an ECC circuit capable of correcting, from an information code and a check code stored in said information storing part, an error of said information code to x bits,
wherein in said information storing part with reference to said ECC circuit, the storing location of said information code is allocated to the position capable of inputting and outputting information faster than the storing location of said check code.

6. A test method of a semiconductor memory device including:
an information storing part for storing an m-bit information code and an n-bit check code for one piece of position information;
an ECC circuit capable of correcting, from an information code and a check code stored in said information storing part, an error of said information code to x bits;
and a test circuit for receiving an information code and a check code stored in said information storing part,
wherein an information code and a check code for test with the same bits are stored in said information storing part, said stored information code and check code for test are transmitted to said test circuit, and a defect with said x+1 bits or more for one piece of position information is decided as being defective.

7. The test method of a semiconductor memory device according to claim 6,
wherein said semiconductor memory device includes:
a plurality of information storing parts accessible individually;
a plurality of test circuits corresponding to said plurality of information storing parts, respectively; and
an ECC circuit provided to be shared corresponding to said plurality of information storing parts,
wherein said plurality of information storing parts store an information code and a check code for test in the same pattern, and said plurality of test circuits are valid in parallel in test mode, each deciding a defect with said x+1 bits or more as being defective for outputting individually.

8. The test method of a semiconductor memory device according to claim 6,
wherein said semiconductor memory device includes a z-bit information input/output terminal in which the relation of z>n is established,
wherein at information input in test mode, an information input terminal with n bits of said z bits is used to be written as an n-bit check code into said information storing part and an information input/output terminal with the remaining z−n bits or less is used to be written thereinto as an information code of said information storing part.

9. The test method of a semiconductor memory device according to claim 8,
wherein an information code and a check code stored in said information storing part are used for reading in test mode corresponding to allocation of said information code and check code to the information input/output terminal, used at said information input in test mode.
